(19) United States
(12) Patent Application Publication
(10) Pub. No.: US 2008/0290429 A1
(43) Pub. Date: Nov. 27, 2008

(54) SEMICONDUCTOR DEVICE AND METHOD FOR FABRICATING THE SAME

(75) Inventor: Weon-Chul JEON, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-shi (KR)

(21) Appl. No.: 11/951,206

(22) Filed: Dec. 5, 2007

(30) Foreign Application Priority Data
May 23, 2007 (KR) 10-2007-0050098

(51) Int. Cl. H01L 29/78; H01L 21/283

(52) U.S. Cl. 257/413; 438/592; 257/E21.177; 257/E29.255

(57) ABSTRACT

A method for fabricating a semiconductor device includes forming a gate insulation layer over a substrate, a first conductive layer over the gate insulation layer, and a second conductive layer over the first conductive layer, etching the second conductive layer to form a second gate electrode using a first mask pattern having a first width, forming an insulation layer over a resultant where the second gate electrode is formed, and etching the insulation layer, the first conductive layer and the gate insulation layer sequentially to form a gate using a second mask pattern having a second width greater than the first width, the gate including an etched gate insulation layer, a first gate electrode, the second gate electrode, and a gate hard mask, which are stacked in sequence, wherein both sidewalls and a top surface of the second gate electrode are covered with the gate hard mask.

### CROSS-REFERENCE TO RELATED APPLICATIONS

The present invention claims priority of Korean patent application number 10-2007-0050098, filed on May 23, 2007, which is incorporated by reference in its entirety.

### BACKGROUND OF THE INVENTION

The present invention relates to a method for fabricating a semiconductor device, and more particularly, to a semiconductor device having a gate and a method for fabricating the same.

A gate includes a gate insulation layer, a gate electrode and a gate hard mask, which are sequentially stacked over a substrate. In general, the gate electrode has a stacked structure where a metal layer or a metal silicide layer is formed on a polysilicon layer. In semiconductor memory devices such as dynamic random access memory (DRAM), a landing plug contact process and a bit line contact process should be sequentially performed in advance so as to form a bit line after forming the gate.

FIGS. 1A and 1B illustrate an electrical short between a gate electrode and a bit line in a typical method for fabricating a semiconductor device. FIG. 1B illustrates a cross-sectional view taken along line A-A′ of FIG. 1A.

Referring to FIGS. 1A and 1B, an isolation layer 11 is formed in a substrate 10 to define an active region. A stacked gate 12 including a gate insulation layer 12A, a polysilicon gate electrode 12B, a tungsten gate electrode 12C and a gate hard mask 12D is formed over the substrate 10 through an aforementioned method, and thereafter a gate spacer 13 is formed on the sidewalls of the gate 12.

A source/drain ion implantation is performed to form a junction region (not shown) in the active region of the substrate 10 between the gates 12. The junction region is divided into two regions, of which one is a bit line junction region to which a bit line will be connected and the other is a storage node junction region to which a storage node will be connected.

A first interlayer dielectric (ILD) layer 14 is formed on a first resultant. The first ILD layer 14 is then etched with a self aligned contact (SAC) etching process to form an opening exposing the substrate 10 between the gates 12.

After a conductive layer, such as a polysilicon layer, is formed to fill the opening, the conductive layer is planarized by chemical mechanical polishing (CMP) until the gate hard mask 12D is exposed, thus forming a landing plug contact 15 contacting the junction region.

A second ILD layer 16 is formed on a second resultant, and the second ILD layer 16 is then selectively etched to form a bit line contact hole 17 exposing the landing plug contact 15 contacting the bit line junction region. A conductive layer 18 is formed to fill the bit line contact hole 17.

However, the typical method as illustrated in FIGS. 1A and 1B has several limitations detailed hereinafter. Generally, there may be a loss to a top portion of the gate hard mask 12D during the CMP process for forming the landing plug contact 15. Hence, when the bit line contact hole 17 is misaligned, the tungsten gate electrode 12C is partially exposed due to an insufficient thickness of the remaining gate hard mask 12D, which leads to the electrical short between the tungsten gate electrode 12C and the bit line conductive layer 18 (see a dotted line in FIG. 1B).

FIGS. 2A to 2D illustrate an electrical short between a gate electrode and a landing plug contact in a typical method for fabricating a semiconductor device.

Referring to FIG. 2A, an isolation layer 21 is formed in a substrate 20 to define an active region. A stacked gate 22 including a gate insulation layer 22A, a polysilicon gate electrode 22B, a tungsten gate electrode 22C and a gate hard mask 22D is formed over the substrate 20 in accordance with the aforementioned method.

A gate reoxidation process is performed to recover etch damage generated during the formation of the gate 22. In the meantime, the tungsten gate electrode 22C may be abnormally oxidized so that an oxide layer 23 is formed thicker on the sidewalls of the tungsten gate electrode 22C than other portions. A nitride layer 24 for a gate spacer is formed on a third resultant structure.

Referring to FIG. 2B, a blanket etching is performed upon the nitride layer 24 for the gate spacer to thereby form an etched gate spacer 24′ on both sidewalls of the gate 22. Since the oxide layer 23 is thickly formed on the sidewalls of the tungsten gate electrode 22C through the gate reoxidation process, the etched gate spacer 24′ becomes thinner at the sidewalls of the tungsten gate electrode 22C than the others. A reference numeral 23′ represents an etched oxide layer which is formed by the blanket etching on the oxide layer 23.

Referring to FIG. 2C, an ILD layer 25 is formed on a fourth resultant and the ILD layer is then etched with a self align contact (SAC) etching process to form an opening 26 exposing the substrate 20 between the gates 22. As described above, the etched gate spacer 24′ is thinned at the sidewalls of the tungsten gate electrode 22C compared to the other portions so that the etched gate spacer 24′ at the sidewalls of the tungsten gate electrode 22C is susceptible to being lost during the SAC etching process, thus partially exposing the etched oxide layer 23′ formed on the sidewalls of the tungsten gate electrode 22C during the gate reoxidation process (see a dotted line in FIG. 2C). A reference numeral 24″ represents a thinned gate spacer which is formed by performing the SAC process on the etched gate spacer 24′.

Referring to FIG. 2D, a conductive layer 27 for a landing plug contact is formed to fill an opening 26 after performing a wet cleaning process. In the meantime, the etched oxide layer 23′ is also removed during the wet cleaning process, causing the electrical short between the tungsten gate electrode 22C and the conductive layer 27 for the landing plug contact (see dotted line in FIG. 2D).

Therefore, it is necessary to develop a method which can prevent the electrical short between a gate electrode and a landing plug contact and an electrical short between the gate electrode and a bit line.

### SUMMARY OF THE INVENTION

Embodiments of the present invention relate to a semiconductor device and a method for fabricating the same, which can prevent an electrical short between a gate electrode and a landing plug contact and an electrical short between the gate electrode and a bit line by a gate hard mask covering a top surface and both sides of a gate electrode in a gate.

In accordance with an aspect of the present invention, there is provided a method for fabricating a semiconductor device including: forming a gate insulation layer over a substrate, a first conductive layer over the gate insulation layer, and a second conductive layer over the first conductive layer; etching the second conductive layer to form a second gate electrode using a first mask pattern having a first width; forming an insulation layer over a first resultant where the second gate electrode is formed; and etching the insulation layer, the first conductive layer and the gate insulation layer sequentially to form a gate using a second mask pattern having a second width greater than the first width, the gate including an etched gate insulation layer, a first gate electrode, the second gate electrode, and a gate hard mask, which are stacked in sequence, wherein both sidewalls and a top surface of the second gate electrode are covered with the gate hard mask.

In accordance with another aspect of the present invention, a semiconductor device is provided. The semiconductor device includes a transistor having a gate, wherein the gate includes a gate insulation pattern over a substrate, a first gate electrode over the gate insulation pattern, a second gate electrode over the first gate electrode, and a gate hard mask over the second gate electrode, wherein both surfaces of sidewalls and a top surface of the second gate electrode are covered with the gate hard mask.

### BRIEF DESCRIPTION OF THE DRAWINGS

FIGS. 1A and 1B illustrate an electrical short between a gate electrode and a bit line in a typical method for fabricating a semiconductor device.

FIGS. 2A to 2D illustrate an electrical short between a gate electrode and a landing plug contact in a typical method for fabricating a semiconductor device.

FIGS. 3A to 3F illustrate a method for fabricating a semiconductor device in accordance with an embodiment of the present invention.

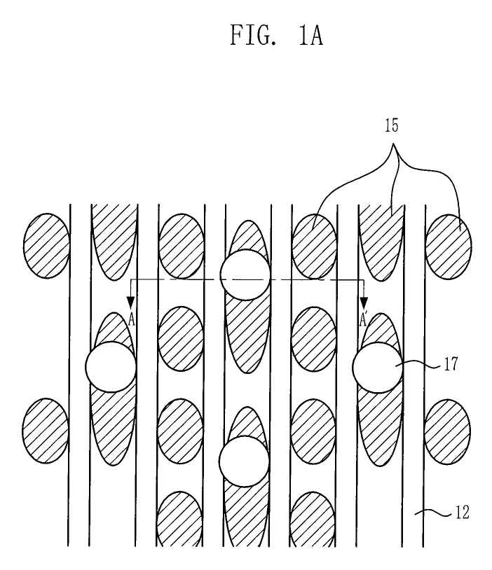

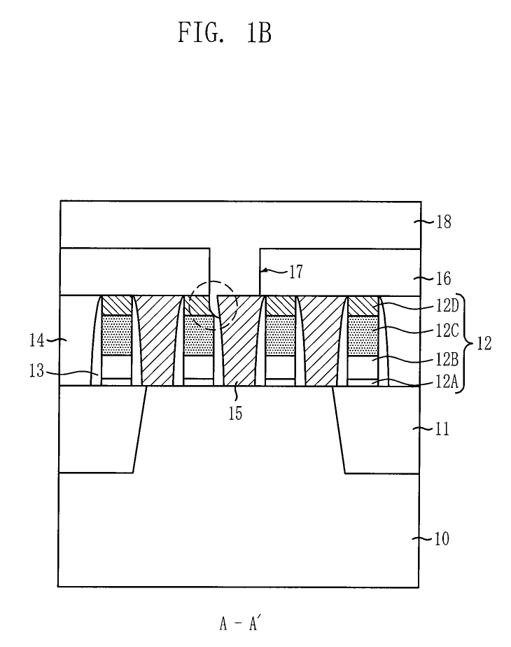

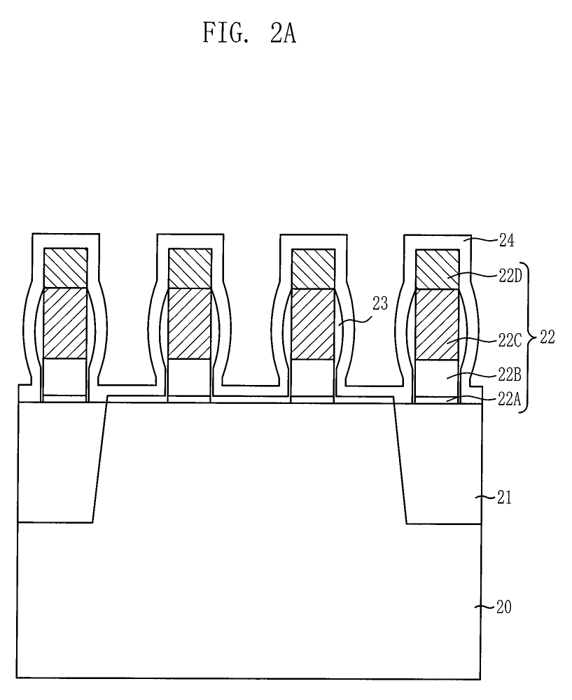

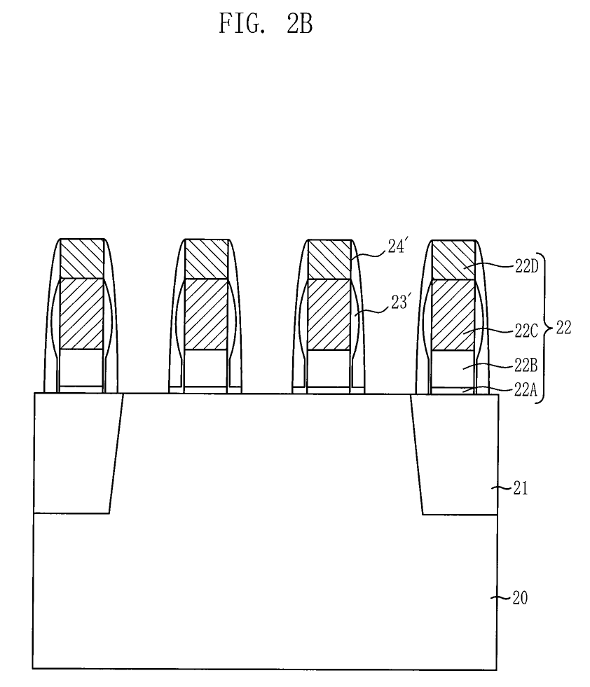

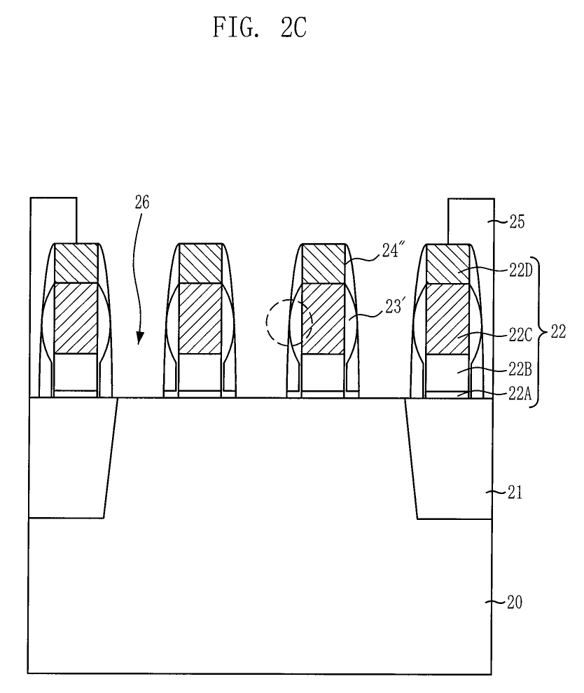

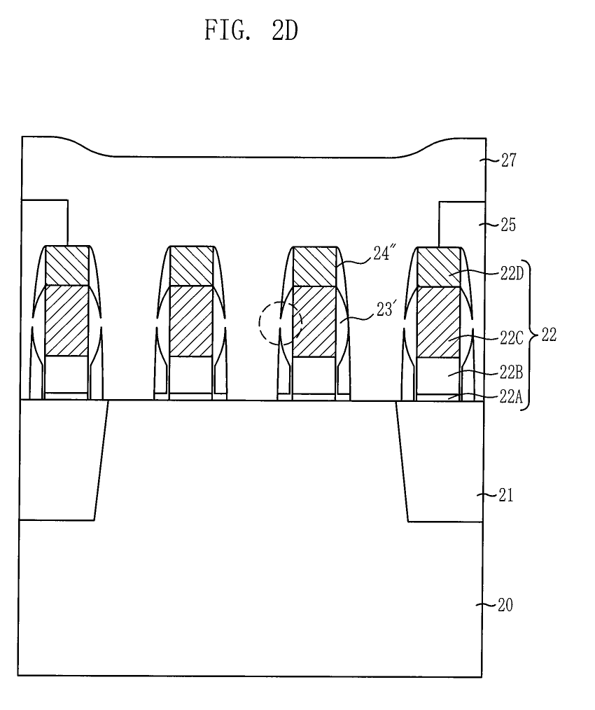

### DESCRIPTION OF SPECIFIC EMBODIMENTS

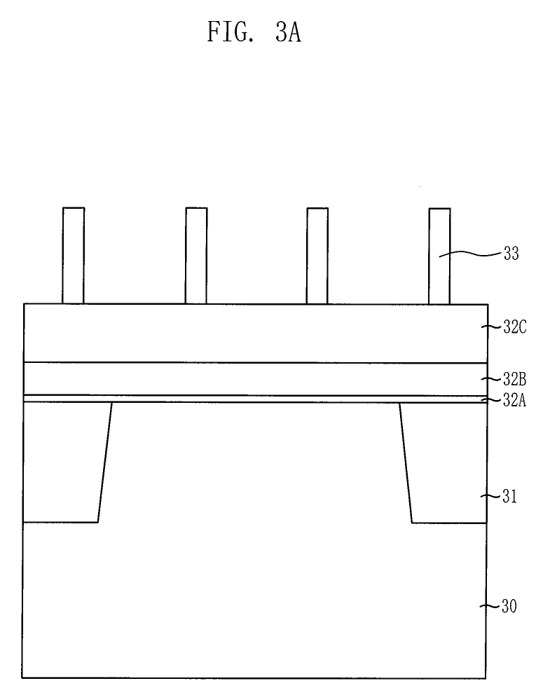

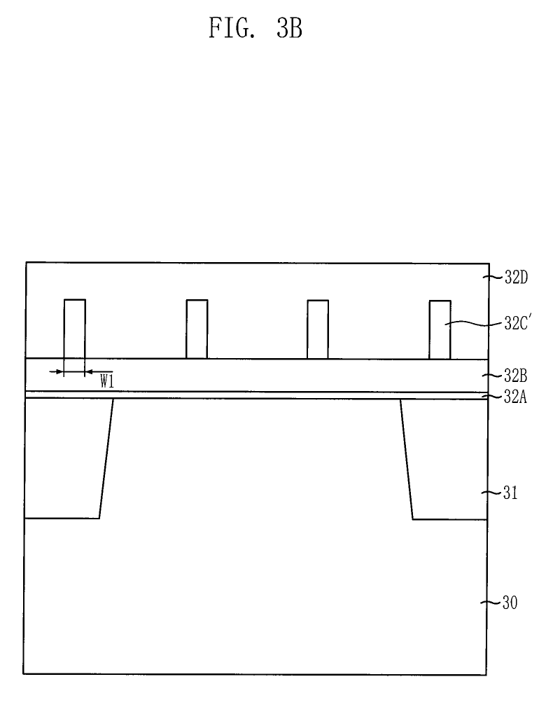

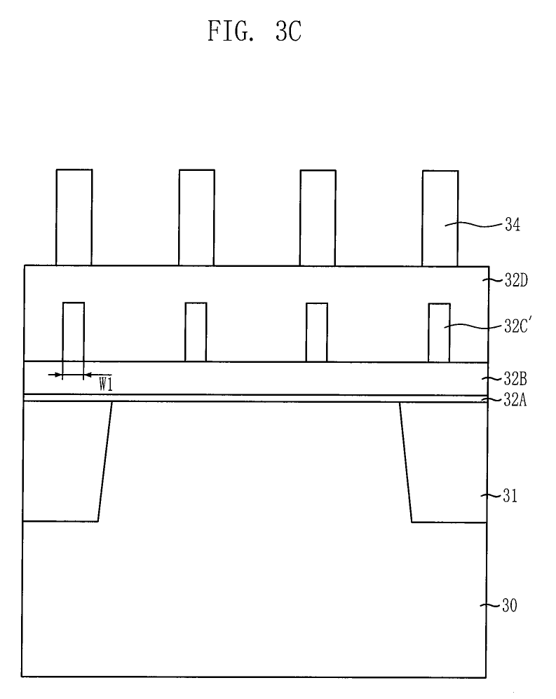

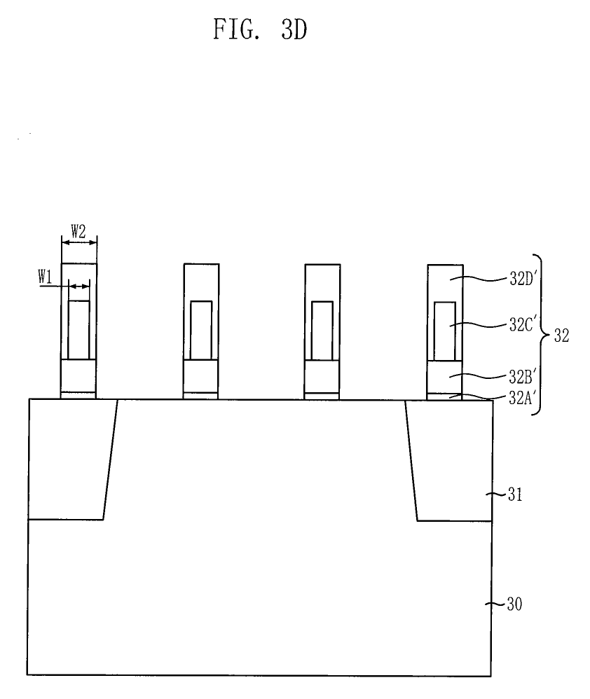

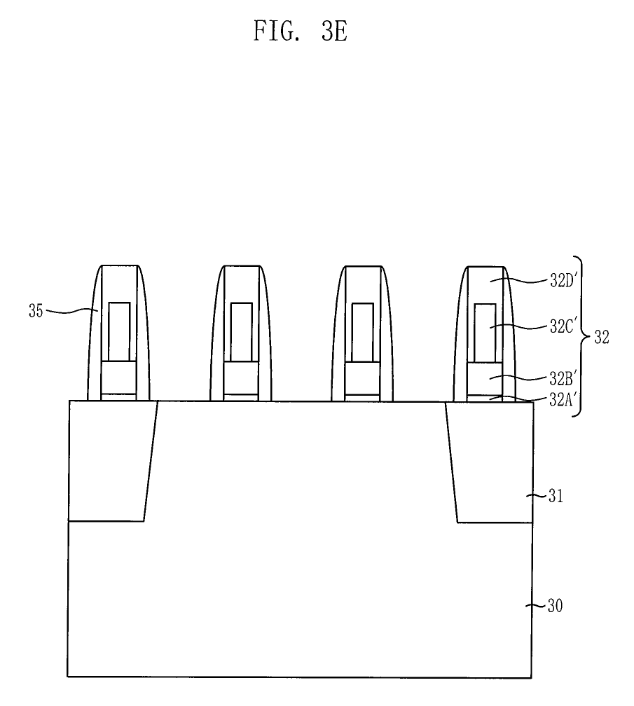

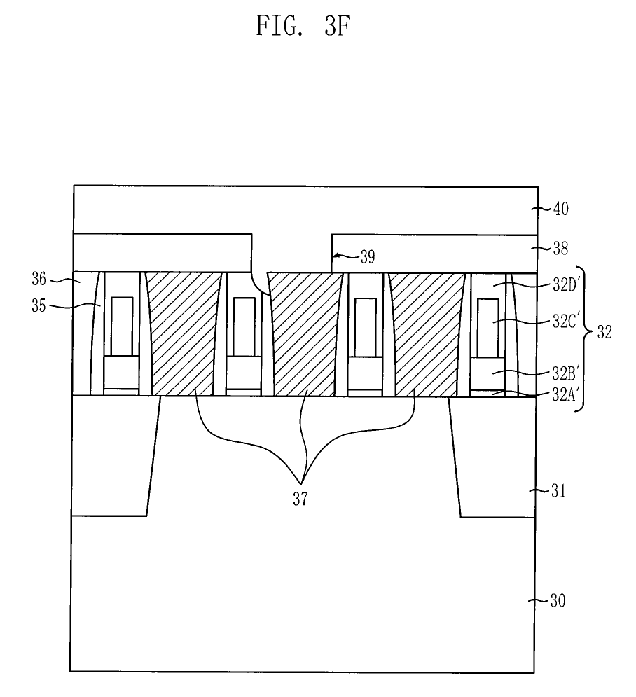

FIGS. 3A to 3F illustrate a method for fabricating a semiconductor device in accordance with an embodiment of the present invention.

Referring to FIG. 3A, an isolation layer 31 is formed in a substrate 30 to define an active region. A gate insulation layer 32A, a first gate electrode 32B, and a second gate electrode 32C are sequentially formed over the substrate 30. The first gate electrode 32B includes a polysilicon layer and the second gate electrode 32C includes a tungsten layer. Alternatively, another metal layer or metal silicide layer such as tungsten silicide layer may be used as a conductive layer for the gate electrode instead of the tungsten layer 32C for the gate electrode.

A first photoresist pattern 33 is formed over the tungsten layer 32C so as to pattern the tungsten layer 32C. The first photoresist pattern 33 may have a width smaller than a width of a second photoresist pattern (FIG. 3C) used in a succeeding formation of a gate.

Referring to FIG. 3B, the tungsten layer 32C is etched by using the first photoresist pattern 33 as an etch barrier, thereby forming an etched tungsten gate electrode 32C′. A width of the etched tungsten gate electrode 32C′ is represented as W1, which corresponds to the width of the first photoresist pattern 33.

After removing the first photoresist pattern 33, an insulation layer 32D for a gate hard mask is formed over a first resultant where the etched tungsten gate electrode 32C′ is formed. The insulation layer 32D for a gate hard mask includes a nitride layer. A planarization process is performed on a nitride layer 32D such that the nitride layer 32D is higher than the tungsten gate electrode 32C′. That is, the nitride layer 32D has a planarized top surface which is higher than a top surface of the etched tungsten gate electrode 32C′.

Referring to FIG. 3C, a second photoresist pattern 34 is formed over the nitride layer 32D so as to form a gate region. The second photoresist pattern 34 is formed at a position so that it can overlap the first photoresist pattern 33, and has a greater width than the first photoresist pattern 33.

Referring to FIG. 3D, the nitride layer 32D, the polysilicon layer 32B and the gate insulation layer 32A are sequentially etched by using the second photoresist pattern 34 as an etch barrier, thus forming a gate 32 configured with a etched gate insulation layer 32A′, a polysilicon gate electrode 32B′, an etched tungsten gate electrode 32C′ and a gate hard mask 32D′. Afterwards, the second photoresist pattern 34 is removed. A width of the gate 32 is represented as W2, which corresponds to the width of the second photoresist pattern 34.

In the gate 32 formed through the above-described processes, the etched gate insulation layer 32A′, the polysilicon gate electrode 32B′ and the gate hard mask 32D′ are stacked in sequence, and the gate hard mask 32D′ covers a top surface and both sides of the etched tungsten gate electrode 32C′ on the polysilicon gate electrode 32B′.

A gate reoxidation process is performed to recover etch damage generated during the formation of the gate 32. In the present invention, since the etched tungsten gate electrode 32C′ is covered with the gate hard mask 32D during the gate reoxidation process, an abnormal oxidation of the etched tungsten gate electrode 32C′ does not take place.

Referring to FIG. 3E, a nitride layer for a gate spacer is deposited over a second resultant including the gate 32, and a blanket etching is performed on the nitride layer to form a gate spacer 35 on both sidewalls of the gate 32.

A source/drain ion implantation is performed to form a junction region (not shown) in the active region of the substrate 30 between the gates 32. The junction region is divided into two regions, of which one is a bit line junction region to which a bit line will be connected and the other is a storage node junction region to which a storage node will be connected.

Referring to FIG. 3F, a first interlayer dielectric (ILD) layer 36 is formed on a third resultant structure. The first ILD layer 36 is etched using a self aligned contact (SAC) process to form an opening exposing the substrate 30 between the gates 32 over the active region.

After a conductive layer (e.g., polysilicon layer) is formed to fill the opening, the conductive layer is planarized by a chemical mechanical polishing (CMP) process until the gate hard mask 32D′ is exposed, thus forming a landing plug contact 37 contacting the junction region. Since the etched tungsten gate electrode 32C′ is covered with the gate hard mask 32D′, the electrical short between the etched tungsten gate electrode 32C′ and the landing plug contact 37 is not generated.

A second ILD layer 38 is formed on a fourth resultant, and the second ILD layer 38 is then selectively etched to form a bit line contact hole 39 exposing the landing plug contact 37 contacting the bit line junction region. A conductive layer 40 is formed to fill the bit line contact hole 39. since a process margin increases due to the etched tungsten gate electrode 32C′ covered with the gate hard mask 32D′, although the bit line contact hole 39 is misaligned, the electrical short between the etched tungsten gate electrode 32C′ and the bit line conductive layer 40 can be prevented.

In a semiconductor device and a method for fabricating the same in accordance with the embodiment of the present invention, it is possible to prevent an electrical short between a gate electrode and a landing plug contact, and another electrical short between the gate electrode and a bit line by a gate hard mask covering a top surface and both sides of a gate electrode in a gate pattern.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

For example, the present invention is also applicable to a gate pattern formed in a recess obtained by etching a substrate to a predetermined depth. That is, the present invention can be applied to a method for fabricating a semiconductor device having a recess gate pattern.

What is claimed is:

1. A method for fabricating a semiconductor device, the method comprising:
forming a gate insulation layer over a substrate, a first conductive layer over the gate insulation layer, and a second conductive layer over the first conductive layer;
etching the second conductive layer to form a second gate electrode using a first mask pattern having a first width;
forming an insulation layer over a first resultant where the second gate electrode is formed; and
etching the insulation layer, the first conductive layer and the gate insulation layer sequentially to form a gate using a second mask pattern having a second width greater than the first width, the gate including an etched gate insulation layer, a first gate electrode, the second gate electrode, and a gate hard mask, which are stacked in sequence,
wherein both sidewalls and a top surface of the second gate electrode are covered with the gate hard mask.

2. The method of claim 1, wherein the second conductive layer includes a metal layer or a metal silicide layer, or both.

3. The method of claim 2, wherein the second conductive layer includes a tungsten layer or a tungsten silicide layer, or both.

4. The method of claim 1, wherein the first conductive layer includes a polysilicon layer.

5. The method of claim 1, wherein the insulation layer includes a nitride layer, and has a planarized surface higher than the second gate electrode.

6. The method of claim 1, further comprising performing a gate re-oxidation process after the gate is formed.

7. The method of claim 1, further comprising, after the forming of the gate:
forming a first interlayer dielectric (ILD) layer over a second resultant where the gate is formed;
etching the first ILD layer using a self aligned contact (SAC) process to form an opening exposing the substrate between the gates;
forming a conductive layer filling the opening; and
performing a planarization until the gate hard mask is exposed, to thereby form a landing plug contact.

8. The method of claim 7, further comprising, after the forming of the landing plug contact:
forming a second ILD layer on a third resultant structure;
selectively etching the second ILD layer to form a bit line contact hole; and
forming a bit line conductive layer filling the bit line contact hole.

9. The method of claim 1, wherein the substrate has a recess overlapping the gate pattern.

10. A semiconductor device, comprising a transistor including a gate, wherein the gate includes a gate insulation pattern over a substrate, a first gate electrode over the gate insulation pattern, a second gate electrode over the first gate electrode, and a gate hard mask over the second gate electrode, wherein both surfaces of sidewalls and a top surface of the second gate electrode are covered with the gate hard mask.

11. The semiconductor device of claim 10, wherein the second conductive layer includes a metal layer or a metal silicide layer, or both.

12. The semiconductor device of claim 11, wherein the second conductive layer includes a tungsten layer or a tungsten silicide layer, or both.

13. The semiconductor device of claim 10, wherein the first conductive layer includes a polysilicon layer.

14. The semiconductor device of claim 10, wherein the gate hard mask includes a nitride layer.

15. The semiconductor device of claim 10, wherein the substrate has a recess overlapping the gate.
